(19) United States
(12) Patent Application Publication
(10) Pub. No.: US 2003/0192646 A1
(43) Pub. Date: Oct. 16, 2003

(54) Plasma processing chamber having magnetic assembly and method

(75) Inventors: Robert W. Wu, Pleasanton, CA (US); Wing L. Cheng, Sunnyvale, CA (US); You Wang, Cupertino, CA (US); Senh Thach, Union City, CA (US); Hamid Noorbakhsh, Fremont, CA (US); Kwok Manus Wong, San Jose, CA (US); Jennifer Y. Sun, Sunnyvale, CA (US)

Correspondence Address: JANAH & ASSOCIATES A PROFESSIONAL CORP, 650 DELANCEY STREET, SUITE 106, SAN FRANCISCO, CA, 941072001

(73) Assignee: Applied Materials, Inc.

(21) Appl. No.: 10/122,271

(22) Filed: Apr. 12, 2002

(51) Int. Cl. C23F 1/00; C23C 16/00

(52) U.S. Cl. 156/345.49; 156/345.42; 156/345.46; 156/345.51; 118/723 MA; 118/723 MR; 118/728

(57) ABSTRACT

A magnetic assembly for a plasma processing chamber includes an annular housing having a radially outward face and a radially inwardly facing opening, a cover plate to seal the radially inwardly facing opening, and a plurality of magnets in the annular housing. The magnets may be in preassembled modules that abut one another in a ring configuration within the annular housing. A plasma processing chamber using the magnetic assembly includes a substrate support that can fit in an inner radius of the magnetic assembly, a gas supply to maintain process gas at a pressure in the chamber, a gas energizer to energize the process gas, and an exhaust to exhaust the process gas.

### BACKGROUND

Embodiments of the present invention relate to a plasma processing chamber having a magnetic assembly and methods of manufacture.

A plasma processing chamber exposes a substrate to a plasma capable of processing the substrate. Typically, the chamber comprises a substrate support to support the substrate, a gas distributor to introduce process gas into the chamber, and a gas exhaust to exhaust the gas from the chamber. In certain chambers, a magnetic assembly is used to control the passage of plasma species into an exhaust channel of the chamber that may extend around the substrate support and is used to exhaust process gas from the chamber. For example, the magnetic assembly may be used to limit the passage of charged plasma species into the exhaust channel. The magnetic assembly may also be positioned around the substrate support to generate a magnetic field about the support to localize, excite, or contain the plasma, in or about the substrate processing zone in the chamber.

One type of magnetic assembly comprises a housing in which a number of permanent magnets are positioned as for example described in commonly assigned U.S. patent application No. 6,074,512 filed on Jul. 15^{th}, 1997 to Collins et al. The magnets are sealed in an epoxy medium to prevent movement of the magnets within the housing. Typically, as shown in FIG. 1, the housing has a top or bottom opening 15 that is sealed by a cover plate 20 that is welded along its edges 21 to the sidewalls of the housing 22. However, the welded interface 21 between the cover plate 20 and the housing 22 can erode when exposed to the plasma in the chamber. When holes are formed in the weld lines 21 or adjacent portions of the housing, the material inside the housing 22, such as the epoxy that is used to hold the magnets 25 in place, can burn or otherwise deteriorate having undesirable effects on the substrate being processed and the magnetic assembly itself. For example, the magnets 25 can become damaged when the plasma 17 penetrates into the housing 22. Permanent magnets which are made of rare earth containing materials are expensive and it would be desirable to remove the magnets from a damaged magnetic assembly and reuse the magnets. Thus it is desirable to have a magnetic assembly and housing that is more resistant to plasma erosion and that can be more easily used in refurbishment processes.

It is also difficult to manufacture such magnetic assemblies especially when a large number of magnets have to be precisely aligned to one another inside the housing. Often, some of the magnets become misaligned during assembly and this results in the magnetic assembly providing a undesirable magnetic field distribution. Thus, it is further desirable to have a magnetic assembly and manufacturing process that allows easier assembly and alignment of the magnets in the housing.

### SUMMARY

A magnetic assembly for a plasma processing chamber, the magnetic assembly comprising:

(a) an annular housing having a radially outward face and a radially inwardly facing opening;

(b) a cover plate to seal the radially inwardly facing opening; and

(c) a plurality of magnets in the annular housing.

A magnetic assembly for a plasma processing chamber, the magnetic assembly comprising:

(a) an annular housing having a radially outward face and a radially inwardly facing opening;

(b) a cover plate joined to the housing to seal the radially inwardly facing opening; and

(c) a plurality of preassembled modules abutting one another in the annular housing, each preassembled module comprising a plurality of magnets.

A plasma processing chamber comprising the magnetic assembly of claim 9, the chamber comprising:

(i) a substrate support sized to fit within the magnetic assembly;

(ii) a gas supply to maintain process gas at a pressure in the chamber;

(iii) a gas energizer to energize the process gas to process the substrate; and

(iv) an exhaust to exhaust the process gas from the chamber.

A plasma processing chamber comprising:

(a) a magnetic assembly comprising:

(i) an annular housing having a radially outward face and a radially inwardly facing opening;

(ii) a cover plate joined to the housing to seal the radially inwardly facing opening; and

(iii) a plurality of preassembled modules abutting one another in a plurality of ring configurations, the ring configurations being stacked on one another in the annular housing, the preassembled modules abutting one another within each ring configuration, and each preassembled module comprising a plurality of magnets;

(b) a substrate support sized to fit within an inner radius of the magnetic assembly;

(c) a gas supply to maintain process gas at a pressure in the chamber;

(d) a gas energizer to energize the process gas to process the substrate; and

(e) an exhaust to exhaust the process gas from the chamber.

A method of manufacturing a magnetic assembly for a plasma processing chamber, the method comprising:

(a) providing an annular housing having a radially outward face and a radially inwardly facing opening;

(b) inserting a plurality of magnets into the annular housing through the radially inwardly facing opening; and

(c) joining a cover plate to the annular housing to seal the radially inwardly facing opening.

A method of refurbishing a magnetic assembly for a plasma processing chamber, the magnetic assembly comprising a first annular housing containing a plurality of preassembled modules comprising magnets, the first annular housing having a radially outward face and a radially inwardly facing opening, the radially inwardly facing opening sealed by a cover plate, the method comprising:

(a) removing the cover plate from the first annular housing;

(b) removing the preassembled modules from the first annular housing;

(c) inserting the preassembled modules into a second annular housing, the second annular housing having a radially outward face and a radially inwardly facing opening; and

(d) joining a second cover plate to the second annular housing.

### DRAWINGS

These features, aspects, and advantages of the present invention will become better understood with regard to the following description, appended claims, and accompanying drawings which illustrate examples of the invention. However, it is to be understood that each of the features can be used in the invention in general, not merely in the context of the particular drawings, and the invention includes any combination of these features, where:

FIG. 1 (Prior Art) is a cross-sectional side view of a portion of a plasma processing chamber having a conventional magnetic assembly;

FIG. 2 is a cross-sectional side view of a plasma processing chamber having an embodiment of a magnetic assembly according to the present invention;

FIG. 3 is an exploded perspective view of an embodiment of a magnetic assembly showing a preassembled module that fits in the annular housing of the magnetic assembly;

FIG. 4 is a view of a portion of the chamber of FIG. 2 showing the anode shield, cathode shield, and a magnetic assembly; and

FIG. 5 is a perspective partial cut-out view of a portion of the magnetic assembly of FIG. 3 showing preassembles modules abutting one another to form stacked rings of the modules within the annular housing of the magnetic assembly.

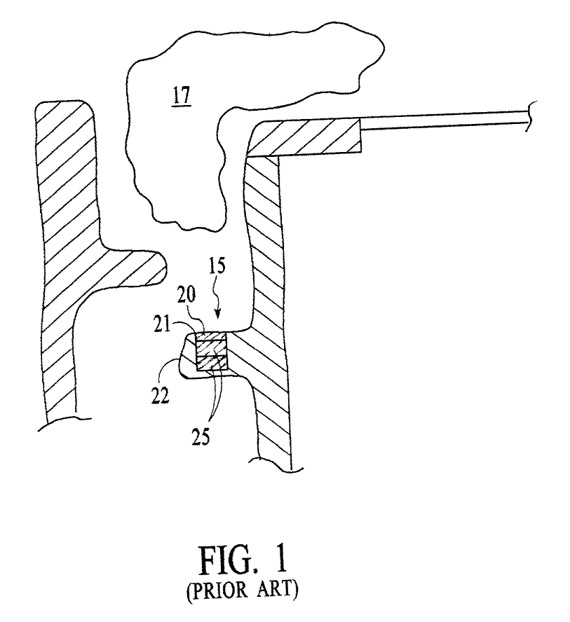

### DESCRIPTION

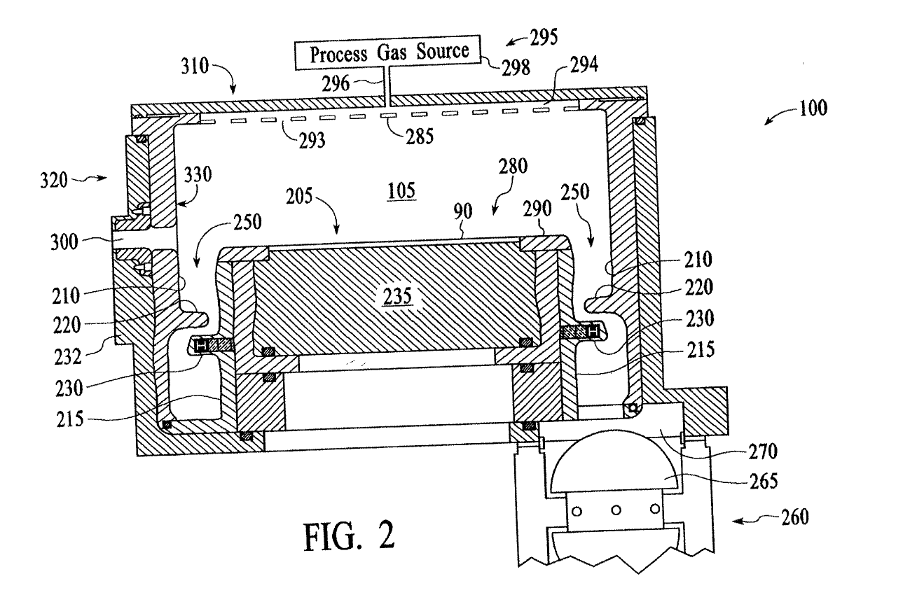

A semiconductor fabrication process may be used to deposit material on or etch a substrate 90 in a plasma processing chamber 100, such as for example, a DIELECTRIC ETCH MxP+ CENTURA chamber, commercially available from Applied Materials Inc., Santa Clara, Calif., as illustrated in FIG. 2. The particular embodiment of the process chamber 100 shown herein, which is suitable for processing of semiconductor substrates 90, is provided only to illustrate the invention, and should not be used to limit the scope of the invention. Other process chambers capable of energizing a process gas, for example an IPS chamber, also available from Applied Materials Inc., can also be used. Generally, the chamber 100 comprises a substrate support 205 having a surface to support the substrate 90 in a process zone 105 of the chamber 100. The substrate support 205 may comprise a quartz dielectric ring 290 that surrounds the substrate 90 to protect the underlying surface of the support 205 from the plasma. The substrate 90 is held in place during the process using a mechanical or electrostatic chuck having a receiving surface with grooves (not shown) in which a coolant gas, such as helium, is held to control the temperature of the substrate 90. The chamber 100 encloses a process zone 105 with, for example, a top wall 310 and side walls 320. An aperture 300 in the chamber 100, such as in a side wall 320 as shown, is provided to allow the substrate 90 to be transferred into and out of the chamber 100.

For example, to perform an etching process, the process chamber 100 is evacuated to a pressure of less than about 1 mTorr, and a substrate 90 is transferred to the substrate support 205 from a load lock transfer chamber (not shown), which is also at vacuum. The chamber 100 comprises a gas supply 295 to maintain a process gas at a suitable pressure in the chamber 100. In one embodiment, the process chamber 100 is maintained at a pressure ranging from about 1 to about 1000 mTorr, such as from 10 to 300 mTorr. The process gas is introduced into the chamber 100 through a gas distributor 285 of a gas supply 295 comprising one or more gas lines 296 that connect a process gas source 298 to an inlet manifold 294 of the gas distributor 285 that conveys process gas through apertures 293 into the process zone 105. The gas distributor 285 may comprise a showerhead plate that is located above the substrate 90 and is made from a dielectric material.

The chamber 100 further comprises a gas energizer 280 to energize the process gas to process the substrate 90. Typically, the gas energizer 280 couples an electric field to the process gas in the process zone 105 to energize the process gas (i) inductively by applying an RF current to an inductor coil (not shown) encircling the process chamber 100, (ii) capacitively by applying an RF current to a cathode electrode 235 and an anode electrode 232, such as the side wall 320 (as shown), or (iii) both inductively and capacitively.

The gas energizer 280 comprises an RF power supply (not shown) to apply power to anode and cathode electrodes 232, 235. In reactive ion etching (RIE) processes, the gas energizer 280 typically energizes the process gas by capacitively coupling an RF voltage from the power supply to the cathode electrode 235 at a power level of from about 100 to about 2000 Watts, and by electrically grounding the anode electrode. Alternatively, an RF current at a power level of from about 750 Watts to about 2000 Watts can be applied to an inductor coil (not shown) to inductively couple energy into the process chamber 100 to energize the process gas in the process zone 105. The frequency of the RF current applied to the process electrodes 232, 235 or inductor coil is typically from about 50 kHz to about 60 MHz, such as about 13.56 MHz.

The plasma or energized process gas may be enhanced using electron cyclotron resonance or magnetically enhanced reactors, in which a magnetic field generator, such as electromagnetic coils, are used to apply a magnetic field to the plasma in the process zone 105 to increase the density and uniformity of the energized process gas. The magnetic field may comprise a rotating magnetic field with the axis of the field rotating parallel to the plane of the substrate 90, as described in U.S. Pat. No. 4,842,683, issued Jun. 27, 1989, which is incorporated herein by reference. The magnetic field in the process chamber 100 may be sufficiently strong to enhance the plasma. For example, the magnetic field as measured on the substrate 90 may be less than about 500 Gauss, and more typically from about 10 to about 100 Gauss.

The gas supply 295 further comprises a gas exhaust 260 to exhaust spent process gas and etchant byproducts from the process chamber 100. Typically, the gas supply 295 maintains a pressure of at least about 10⁻³ mTorr in the process zone 105. The gas exhaust 260 comprises a vacuum pump 270 to pump the gas out of the chamber 100. A throttle valve 265 is provided for controlling the pressure in the chamber 100 by regulating the flow of the gas between the process zone 105 and the vacuum pump 270.

The plasma processing chamber 100 may also have an anode shield 210 adjacent to the anode 232 and a cathode shield 215 adjacent to the cathode 235 to shield the anode 232 and cathode 235 from the plasma. The shields 210, 215 facilitate a short “down time” when the processing chamber 100 is wet cleaned using a cleaning solution by protecting the anode 232 and cathode 235 from the cleaning solution. Additionally, the shields 210, 215 may be adapted to adjust a DC bias between the anode 232 and the cathode 235. For example, the shields 210, 215 may be linings of which a surface area, thickness, or placement can be selected to obtain a suitable DC bias. One or more of the shields 210, 215 may comprise a dielectric material to electrically insulate the anode 232 and cathode 235 from the plasma. In the embodiment shown, one or more electrically conductive parts of the chamber walls 310, 320 serve as the anode 232, and an electrically conductive electrode in the substrate support 205 serves as the cathode 235. The anode shield 210 is an inwardly-facing lining at the top and sides of the chamber 100. The cathode shield 215 lines the sides of the cathode 235 and thus the substrate support 205. In one version, the shields 210, 215 comprise annular protrusions 220, 230 that function in combination as an exhaust baffle. For example, the annular protrusions 220, 230 may form an S-shaped channel therebetween to break the flow of gas to the gas exhaust 260.

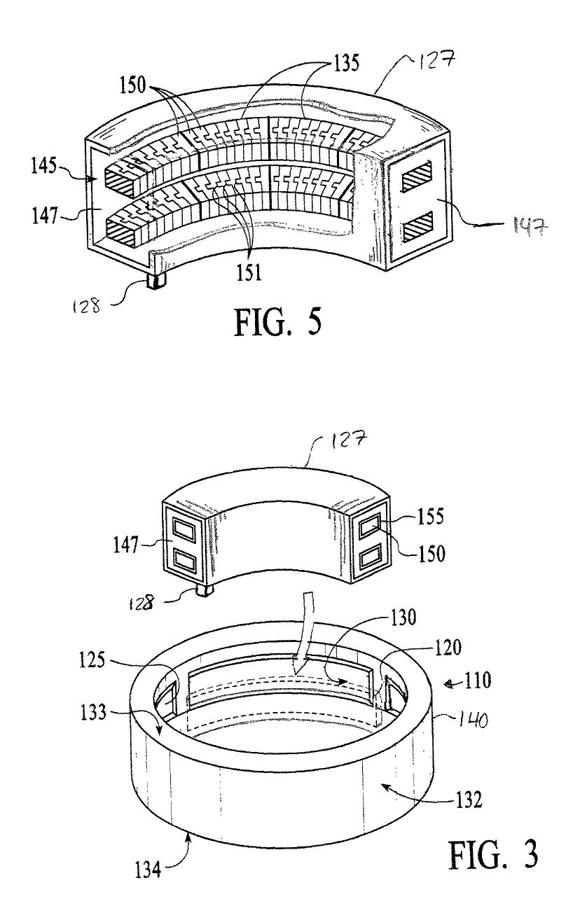

The plasma processing chamber 100 further comprises a magnetic assembly 110 comprising, as shown in FIG. 3, an annular housing 140 having a radially outward face 132 and a radially inwardly facing opening 130, a cover plate 120 to seal the radially inwardly facing opening 130, and a plurality of magnets 150 in the annular housing 140. The radially inward facing opening 130 is sized to allow insertion of the magnets into the housing 140. The annular housing 140 may further comprise top and bottom faces 133, 134, wherein the radially outward face 132 extends from the top face 134 to the bottom face 133, as for example, a continuous unitary structure that is substantially absent welds or other seams.

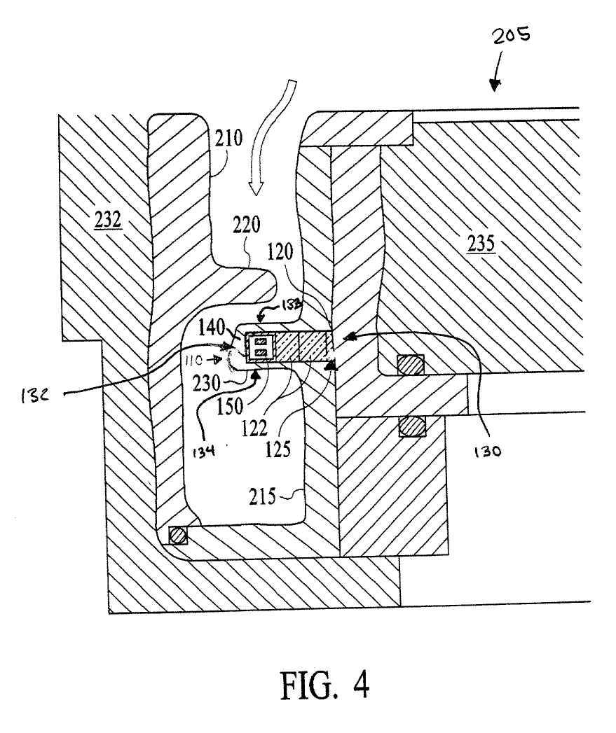

The magnetic assembly 110 typically serves to control a flow path or distribution of the plasma. For example, the magnetic assembly 110 may generate an increasing magnetic field in a path to the gas exhaust 260 to impede or altogether prevent the plasma from extending into the gas exhaust 260. The annular housing 140 may have, for example, a cross-section that is U-shaped or C-shaped, where the concave opening 130 faces radially inwardly. In one embodiment, as shown in FIG. 4, the housing 140 is a protrusion 230 of the cathode shield 215. In this embodiment, the cover plate 120 may be spaced from the magnets 150 by dielectric spacers 122, made from a polymer or ceramic material.

The cover plate 120 is joined to the housing 140, for example, by being welded or soldered to the housing 140, to seal the opening 130. For example, the cover plate 120 may be electron beam welded to the housing 140 by directing an electron beam at an interface between the housing 140 and the cover plate 120 to heat the material at the interface. When the material is sufficiently heated that it melts, the cover plate 120 is pressed onto the housing 140 and the interface material is allowed to cool and solidify. In another embodiment, the cover plate 120 is laser beam welded to the housing 140, which comprises directing a laser beam to the interface between the housing 140 and the cover plate 120. One or more of the housing 140 or cover plate 120 may comprise aluminum to facilitate the welding of the cover plate 120 to the housing 140. In one embodiment, the housing 140 is made of aluminum 6000 and the cover plate 120 is made of aluminum 4000 to facilitate the welding.

The magnets 150 may be arranged in one or more preassembled modules 135, as illustrated in FIG. 4. In one embodiment, each preassembled module 135 comprises from about 20 to about 40 magnets 150. The number of modules 135 may be from about 3 to about 8, such as for example, about 4. For example, if there are a total of about 80 magnets 150 to be placed into four modules, each module 135 would contain 20 magnets 150. The magnets 150 are placed typically abutting one another along an arc-shaped path in the module 135. For example, the magnets 150 may be oriented so that their magnetic north/south poles lie along the arc. In one embodiment, the preassembled modules 135 comprise ring segments containing the magnets 150 abutting one another in a partial ring shaped configuration. In one version, one or more magnetic segments 127 contain preassembled modules 135 arranged in a plurality of ring configurations 145 stacked one above the other. The modules 135 arranged in the ring configurations 145 may be interspaced by portions of the magnetic segments 127. The magnetic segments 127 are inserted into the housing 140 to provide a magnetic field that is substantially parallel to the path of the magnets 150 and with increased relative magnetic field strength closer to the annular housing 140.

The magnets 150 typically comprise a ferromagnet material, such as a rare earth metal. The rare earth metal is able to generate a strong magnetic field relative to the amount used. For example, the magnets 150 may comprise neodymium. In one embodiment, the magnets 150 are held in each preassembled module 135 by a shrink-wrap material 155 around the magnets 150. For example, the shrink-wrap material 155 may comprise polyolefin, teflon (TM), or silicone, which are commercially available from distributors such as Lance Wire & Cable, Inc., Clarkston, Ga., and R. S. Hughe, Sunnyvale, Calif. The magnets 150 are placed in a tube of the shrink-wrap material 155. Then, if the shrink-wrap material 155 is a thermal material, the shrink-wrap material 155 is heated to cause it to contract around the magnets 150. If the shrink-wrap material 155 is a mechanical material, the shrink-wrap material 155 is pressed onto the sides of the magnets 150 to mold it against the magnets 150. The shrink-wrap material 155 improves physical support of the magnets 150 inside the module 135 and thermal distribution in the module 135.

A filler 147 may be provided in the magnetic segments 127 to space or support the preassembled modules 135. In one embodiment, the filler 147 comprises a dielectric material. The filler 147 may abut or surround the magnets 150. In one version, the magnets 150 also comprise keys 151 to align the magnets 150 in the modules 135 and to maintain proper magnetic polarity. For example, this module key 151 may comprise an offset slot or protrusion of the magnet 150 that interlocks with another offset slot or protrusion of another magnet 150. The magnetic segments 127 may also comprise keys 128 that fit to matching slots in the annular housing 140. These alignment keys 128 ensure that the magnetic segments 127 can be positioned when being inserted in the annular housing 140—with proper alignment and magnetic pole orientation.

The substrate support 205 may be sized to fit within an inner radius of the magnetic assembly 110 so that the magnetic assembly 110 encircles the support 205. For example, the housing 140 of the magnetic assembly 110 may comprise the cathode shield 215 and the magnetic segments 127 may be inserted in an opening 135 of the cathode shield 215. In the arrangement shown, the magnetic assembly 110 is near an exhaust path 250 of the gas exhaust 260 to generate a strong magnetic field therein, as shown in FIG. 4, impeding the plasma from escaping from the process zone 105 through the exhaust path 250. When the plasma encounters an increasing magnetic field, it is repelled and the magnetic assembly 110 thus serves as an obstruction to the plasma. The magnetic assembly 110 according to the present invention is less susceptible to erosion than the conventional magnetic assembly because the seal line 125 between the housing 140 and the cover plate 120 is not exposed to the plasma. Instead, the seal line 125 abuts the substrate support 205, preventing the plasma from reaching the seal line 125.

In one version, conductive inner surfaces 330 of the plasma processing chamber 100 are anodized with a protective layer to prevent arcing to the conductive surfaces and to protect the surfaces 330 from erosion by the plasma. In the conventional magnetic assembly (not shown), the surface area of the weld line is difficult to anodize because of the inhomogeneity of the weld line to the surrounding area. In contrast, in the magnetic assembly 110 of the present invention, the seal line 125 between the housing 140 and the cover plate 120 is unexposed to the plasma, so the exposed area can easily be anodized with a protective layer (not shown).

The magnetic assembly 110 may be refurbished for the plasma processing chamber 100. This refurbishment may comprise, for example, removing the modules 135 from an old annular housing 140 and inserting them in a new annular housing 140. The annular housing 140 and magnetic segments 127 sufficiently protect the modules 135 from exposure to plasma, so the magnets 150 can be reused. First, the cover plate is removed from the first annular housing, and the modules 135 are removed from the first annular housing. Then, the modules 135 are inserted into a second annular housing 140, and a second cover plate is bonded to the second annular housing. Typically, the preassembled modules 135 are exchanged between the old and new annular housings by exchanging the magnetic segments 127 containing the preassembled modules 135. In one embodiment, the first annular housing is refinished to form the second annular housing. The first cover plate may also be refinished to form the second cover plate.

Thus, the present plasma processing chamber 100 and method is advantageous because it allows for improved processing of the substrate. Although the present invention has been described in considerable detail with regard to certain preferred versions thereof, other versions are possible. For example, the present invention could be used in a process chamber to deposit a material on a substrate. Thus, the appended claims should not be limited to the description of the preferred versions contained herein.

What is claimed is:

1. A magnetic assembly for a plasma processing chamber, the magnetic assembly comprising:
(a) an annular housing having a radially outward face and a radially inwardly facing opening;
(b) a cover plate to seal the radially inwardly facing opening; and
(c) a plurality of magnets in the annular housing.

2. A magnetic assembly according to claim 1 wherein the annular housing further comprises top and bottom faces, and wherein the radially outward face extends from the top face to the bottom face as a continuous unitary structure.

3. A magnetic assembly according to claim 1 wherein the radially inwardly facing opening is sized to allow insertion of the magnets into the annular housing.

4. A magnetic assembly according to claim 1 wherein the magnets are arranged in one or more preassembled modules, and wherein the radially inwardly facing opening is sized to allow insertion of the preassembled modules into the housing.

5. A magnetic assembly according to claim 4 wherein the preassembled modules abut one another in a ring configuration.

6. A magnetic assembly according to claim 5 further comprising dielectric spacers between the cover plate and the preassembled modules.

7. A magnetic assembly according to claim 4 wherein the magnets are held in each preassembled module by a shrink-wrap material around the magnets.

8. A magnetic assembly according to claim 4 wherein a plurality of the preassembled modules are arranged in a magnetic segment, and the magnetic segment comprises a key to align the magnetic segment in the annular housing.

9. A plasma processing chamber comprising the magnetic assembly of claim 1, the chamber comprising:
(i) a substrate support sized to fit within an inner radius of the magnetic assembly;
(ii) a gas supply to maintain process gas at a pressure in the chamber;
(iii) a gas energizer to energize the process gas to process the substrate; and
(iv) an exhaust to exhaust the process gas from the chamber.

10. A magnetic assembly for a plasma processing chamber, the magnetic assembly comprising:
(a) an annular housing having a radially outward face and a radially inwardly facing opening;
(b) a cover plate joined to the housing to seal the radially inwardly facing opening; and
(c) a plurality of preassembled modules abutting one another in the annular housing, each preassembled module comprising a plurality of magnets.

11. A magnetic assembly according to claim 10 wherein the preassembled modules comprise ring segments.

12. A magnetic assembly according to claim 11 wherein the preassembled modules are arranged in a plurality of ring configurations that are stacked on one another.

13. A magnetic assembly according to claim 10 comprising a plurality of magnetic segments that contain the preassembled modules, the magnetic segments comprising keys for aligning the magnetic segments in the annular housing.

14. A plasma processing chamber comprising the magnetic assembly of claim 9, the chamber comprising:
(i) a substrate support sized to fit within the magnetic assembly;
(ii) a gas supply to maintain process gas at a pressure in the chamber;
(iii) a gas energizer to energize the process gas to process the substrate; and
(iv) an exhaust to exhaust the process gas from the chamber.

15. A plasma processing chamber comprising:
(a) a magnetic assembly comprising:
(i) an annular housing having a radially outward face and a radially inwardly facing opening;
(ii) a cover plate joined to the housing to seal the radially inwardly facing opening; and
(iii) a plurality of preassembled modules abutting one another in a plurality of ring configurations, the ring configurations being stacked on one another in the annular housing, the preassembled modules abutting one another within each ring configuration, and each preassembled module comprising a plurality of magnets;
(b) a substrate support sized to fit within an inner radius of the magnetic assembly;
(c) a gas supply to maintain process gas at a pressure in the chamber;
(d) a gas energizer to energize the process gas to process the substrate; and
(e) an exhaust to exhaust the process gas from the chamber.

16. A method of manufacturing a magnetic assembly for a plasma processing chamber, the method comprising:
(a) providing an annular housing having a radially outward face and a radially inwardly facing opening;
(b) inserting a plurality of magnets into the annular housing through the radially inwardly facing opening; and
(c) joining a cover plate to the annular housing to seal the radially inwardly facing opening.

17. A method according to claim 16 wherein (b) comprises inserting a preassembled module comprising the magnets into the annular housing through the radially inwardly facing opening.

18. A method according to claim 16 comprising joining the cover plate to the annular housing by electron beam welding.

19. A method of refurbishing a magnetic assembly for a plasma processing chamber, the magnetic assembly comprising a first annular housing containing a plurality of preassembled modules comprising magnets, the first annular housing having a radially outward face and a radially inwardly facing opening, the radially inwardly facing opening sealed by a cover plate, the method comprising:
(a) removing the cover plate from the first annular housing;
(b) removing the preassembled modules from the first annular housing;
(c) inserting the preassembled modules into a second annular housing, the second annular housing having a radially outward face and a radially inwardly facing opening; and
(d) joining a second cover plate to the second annular housing.

20. A method according to claim 19 comprising refinishing the first annular housing to form the second annular housing, refinishing the first cover plate to form the second cover plate, and joining the second cover plate to the second annular housing by electron beam welding.
